(19) United States
(12) Patent Application Publication
(10) Pub. No.: US 2015/0137662 A1
(43) Pub. Date: May 21, 2015

(54) APPARATUS AND METHOD OF DRIVING PIEZOELECTRIC ACTUATOR, AND SYSTEM FOR DRIVING PIEZOELECTRIC ACTUATOR USING THE SAME

(71) Applicant: SAMSUNG ELECTRO-MECHANICS CO., LTD., Suwon-Si (KR)

(72) Inventor: Joo Yul KO, Suwon-Si (KR)

(73) Assignee: SAMSUNG ELECTRO-MECHANICS CO., LTD., Suwon-Si (KR)

(21) Appl. No.: 14/280,460

(22) Filed: May 16, 2014

(30) Foreign Application Priority Data
Nov. 21, 2013 (KR) 10-2013-0142465

(51) Int. Cl. H01L 41/04

(52) U.S. Cl. CPC H01L 41/042
USPC 310/317

(57) ABSTRACT

An apparatus for driving a piezoelectric actuator may include: a digital-to-analog conversion unit receiving digital waveform information and outputting an analog signal corresponding thereto; an amplification unit amplifying the analog signal to generate an analog voltage; and a power supply unit supplying power for the amplification. The power supply unit adjusts a level of the power using the digital waveform information.

### CROSS-REFERENCE TO RELATED APPLICATION

This application claims the benefit of Korean Patent Application No. 10-2013-0142465 filed on Nov. 21, 2013, with the Korean Intellectual Property Office, the disclosure of which is incorporated herein by reference.

### BACKGROUND

The present disclosure relates to an apparatus and a method of driving a piezoelectric actuator, and a system for driving a piezoelectric actuator using the same.

With electronic technology becoming ever more advanced, mobile terminals are being reduced in size while being increased in performance. In this regard, piezoelectric technology is one of the most important technologies included in mobile terminals.

As the vibration feature of mobile terminals is required to have high levels of performance and functionality, additional requirements are being created for the piezoelectric technology that allows the vibration feature of mobile terminals to be realized.

The principle of the piezoelectric technology is that an analog voltage is generated, based on digital signals, and is used to drive a piezoelectric element to generate vibrations. When applying piezoelectric technology to mobile terminals, efficiency of analog voltage usage is an important issue.

That is, power to drive a piezoelectric element in a mobile terminal is supplied from the mobile terminal, and thus it may be necessary to utilize the power effectively and in a stable manner.

In existing schemes, voltage supplied from a mobile terminal has been boosted and then used for driving a piezoelectric element. For instance, if the voltage supplied from a mobile terminal is 3.3 V, the voltage may be boosted to 100 V and then used for driving a piezoelectric element.

In such schemes, however, a voltage may be boosted to a maximum level, even though it may not be necessary, i.e., in the case that a small amount of an analog voltage would be sufficient. Accordingly, power may be ineffectively utilized.

### SUMMARY

An aspect of the present disclosure may provide an apparatus and a method of driving a piezoelectric actuator capable of increasing efficiency in boosting and of efficiently managing power by way of performing boosting, according to the level of an analog voltage to be supplied to a piezoelectric element, and a system for driving a piezoelectric actuator using the same.

According to an aspect of the present disclosure, an apparatus for driving a piezoelectric actuator may include: a digital-to-analog conversion unit receiving digital waveform information and outputting an analog signal corresponding thereto; an amplification unit amplifying the analog signal to generate an analog voltage; and a power supply unit supplying power to the amplification unit. The power supply unit may adjust a level of the power using the digital waveform information.

The digital waveform information may include amplitude information relating to the analog voltage.

The digital waveform information may further contain at least one of frequency information and period information relating to an analog voltage to be converted.

The power supply unit may include: a boost converter generating the power; and a boost controller determining a boosting ratio for the boost converter using the amplitude information.

The boost controller may include a plurality of resistance units connected to one another in parallel, and each of the resistance units may include a resistor and a switch connected to each other in series.

The boost controller may perform switching operations on the resistance units using the amplitude information.

According to another aspect of the present disclosure, a system for driving a piezoelectric actuator may include: an apparatus for driving a piezoelectric actuator, the apparatus generating an analog signal corresponding to digital waveform information and amplifying the analog signal to provide an analog voltage; and a piezoelectric element receiving the analog voltage to vibrate, wherein the apparatus utilizes power corresponding to an amplitude of the analog signal.

The apparatus for driving a piezoelectric actuator may include: a digital-to-analog conversion unit receiving digital waveform information and outputting an analog signal corresponding thereto; an amplification unit amplifying the analog signal to generate an analog voltage; and a power supply unit supplying power for the amplification. The power supply unit may adjust a level of the power using the digital waveform information.

The digital waveform information may include amplitude information relating to the analog voltage.

The power supply unit may include: a boost converter generating the power; and a boost controller determining a boosting ratio for the boost converter using the amplitude information.

The boost controller may include a plurality of resistance units connected to one another in parallel, and each of the resistance units may include a resistor and a switch connected to each other in series.

The boost controller may perform switching operations on the resistance units using the amplitude information.

According to another aspect of the present disclosure, a method of driving a piezoelectric actuator may include: receiving digital waveform information and outputting an analog signal corresponding thereto; generating power proportional to amplitude of the analog signal using the digital waveform information; and generating an analog voltage by amplifying the analog signal based on the power.

The digital waveform information may include amplitude information relating to the analog voltage.

The generating of the power may include: adjusting a resistance value using the amplitude information; and generating the power by performing boost converting using the adjusted resistance value.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a typical apparatus for driving a piezoelectric actuator according to an exemplary embodiment of the present disclosure;

FIG. 2 is a block diagram of an example of a typical boost converter;

FIG. 3 is a block diagram of an apparatus for driving a piezoelectric actuator according to an exemplary embodiment of the present disclosure;

FIG. 4 is a diagram showing the boost controller shown in FIG. 3;

FIG. 5 is a block diagram of a system for driving a piezoelectric actuator according to an exemplary embodiment of the present disclosure; and

FIG. 6 is a flowchart for illustrating a method of driving a piezoelectric actuator according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

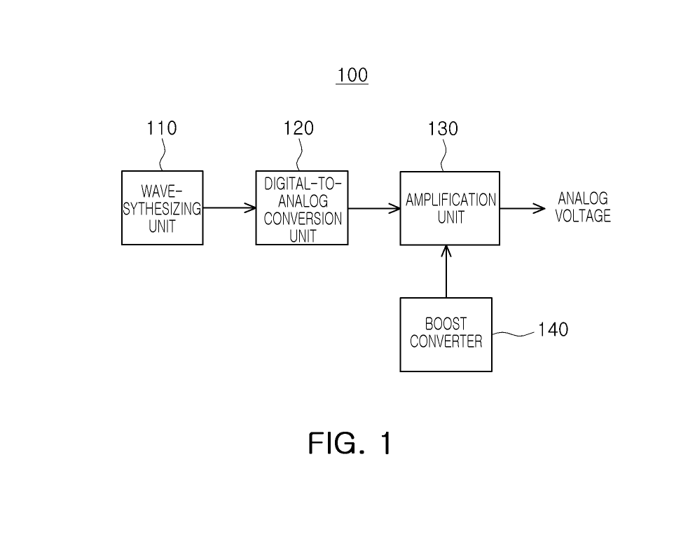

FIG. 1 is a block diagram of a typical apparatus for driving a piezoelectric actuator according to an exemplary embodiment of the present disclosure.

Referring to FIG. 1, the typical apparatus 100 for driving a piezoelectric actuator includes a wave-synthesizing unit 110, a digital-to-analog conversion unit 120, an amplification unit 130, and a boost converter 140.

The wave-synthesizing unit 110 may output digital waveform information.

The digital-to-analog conversion unit 120 may receive the digital waveform information and may output an analog signal corresponding thereto.

The amplification unit 130 may amply the analog signal to generate an analog voltage.

The amplification unit 130 requires a boost voltage of, for example, 50 V to 100 V, higher than a supply voltage. Such a boost voltage is provided by the boost converter 140.

Such a boost converter 140, however, provides a constant supply voltage and thus it is inefficient in terms of power management.

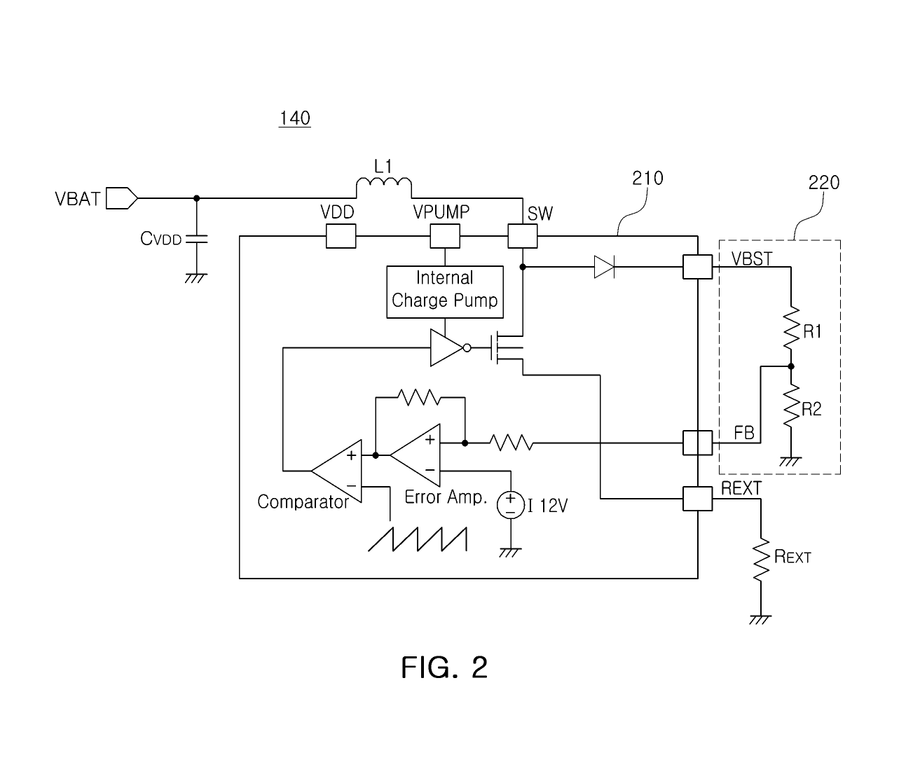

FIG. 2 is a block diagram of an example of a typical boost converter.

The boost converter 140 shown in FIG. 2 includes a boost converter circuit 210 and external resistors 220.

The boost converter 140 shown in FIG. 2 compares a boost voltage determined based on the ratio between the external resistors 220 with a reference value of an error amplifier Error Amp to adjust the output voltage.

Because the boost converter 140 shown in FIG. 2 has the fixed ratio between external resistors 220 and accordingly produces a constant supply voltage independently of the magnitude of an output from the piezoelectric actuator.

Hereinafter, various scheme to drive a piezoelectric actuator that can produce power in accordance with power supplied to the piezoelectric actuator.

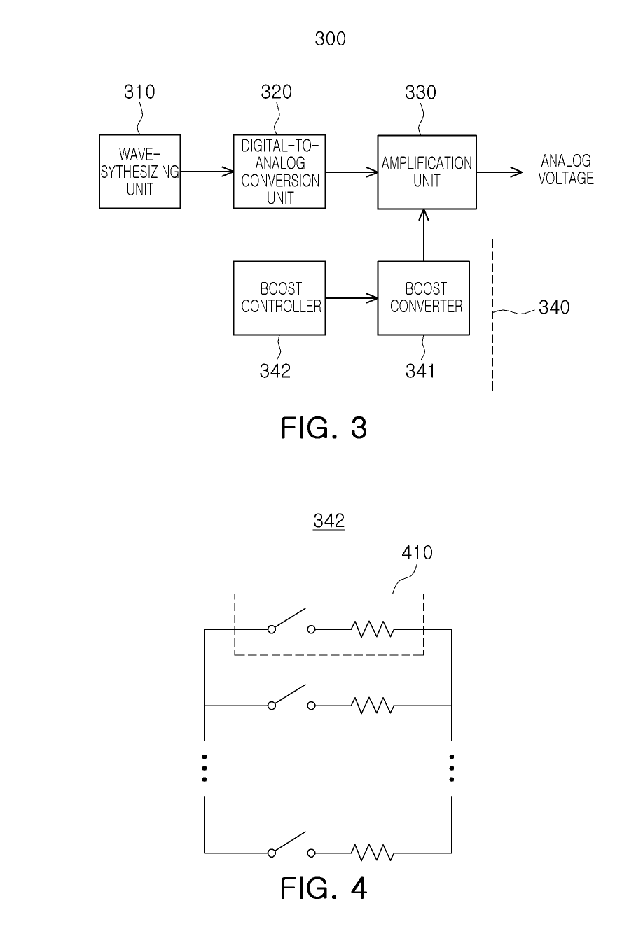

FIG. 3 is a block diagram of an apparatus for driving a piezoelectric actuator according to an exemplary embodiment of the present disclosure.

Referring to FIG. 3, the apparatus 300 for driving a piezoelectric actuator according to the exemplary embodiment may include a wave-synthesizing unit 310, a digital-to-analog conversion unit 320, an amplification unit 330, and a power supply unit 340.

The wave-synthesizing unit 310 may output digital waveform information, and the digital-to-analog conversion unit 320 may receive the digital waveform information to output an analog signal corresponding thereto.

In an exemplary embodiment, the digital-to-analog conversion unit 320 may generate an analog signal by using a previously stored look-up table to output analog values corresponding to certain digital values.

The power supply unit 340 may supply power to the amplification unit 330, and the amplification unit 330 may use the power to amply an analog signal and to generate an analog voltage.

Here, the power supply unit 340 may use the digital waveform information to adjust the level of the power.

If the value of an analog voltage output from the apparatus for driving a piezoelectric actuator is high, an amount of power required by the amplification unit 330 is also high. On the other hand, if the value of an analog voltage output from the apparatus for driving a piezoelectric actuator is low, power required by the amplification unit 330 is sufficient when having a low value.

Therefore, the power supply unit 340 according to the exemplary embodiment of the present disclosure may adjust the level of power provided to the amplification unit 330 according to the level of the analog voltage to be generated by the amplification unit 330.

To this end, the power supply unit 340 may use the digital waveform information to determine the level of the power to be supplied.

The digital waveform information contains amplitude information relating to an analog voltage so that the digital waveform information can be used in determining the level of the power. The power supply unit 340 may determine the level of power so that the power is proportional to the increase and decrease in the amplitude of the analog voltage.

In some exemplary embodiment, the digital waveform information may further contain at least one of frequency information and period information relating to an analog voltage to be converted.

In an exemplary embodiment, the power supply unit 340 may include a boost converter 341 and a boost controller 342.

The boost converter 341 may generate power using a boosting ratio provided from the boost controller 342, and the boost controller 342 may determine a boosting ratio for the boost converter 341 using the amplitude information relating to an analog voltage.

FIG. 4 is a diagram showing the boost controller 342 shown in FIG. 3. An example of the boost controller 342 will be described below with reference to FIG. 4.

The boost controller 342 shown in FIG. 4 may include a plurality of resistance units 410 connected to one another in parallel. Each of the resistance units 410 may include a resistor and a switch connected to each other in series.

In an exemplary embodiment, the boost controller 342 may perform the switching operations on the resistance units 410 using the amplitude information.

In the boost converter shown in FIG. 2, power is generated according to the ratio between the external resistors 220. The ratio between the external resistors 220 is a constant value, and thus the power generated by the boost converter cannot be varied.

In contrast, the boost controller 342 may vary the resistance ratio by using a plurality of resistance units 410, and thus the power generated by the boost converter 341 may be varied.

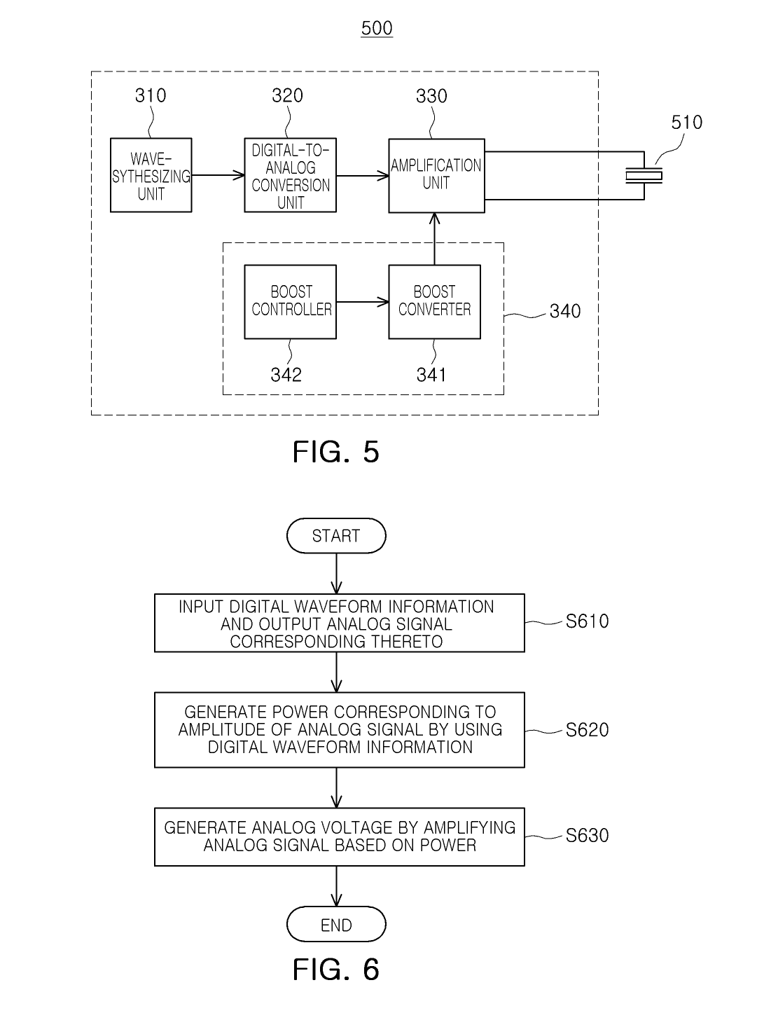

FIG. 5 is a block diagram of a system for driving a piezoelectric actuator according to an exemplary embodiment of the present disclosure.

The system 400 for driving a piezoelectric actuator shown in FIG. 5 may include an apparatus for driving a piezoelectric actuator 330 and a piezoelectric element 510.

The apparatus for driving a piezoelectric actuator 330 may generate an analog signal corresponding to digital waveform information and may amplify the analog signal to provide an analog voltage. The apparatus for driving a piezoelectric actuator 330 has been described above with respect to FIGS. 3 and 4 and, therefore, redundant descriptions thereon will not be made.

The piezoelectric element 510 may receive the analog voltage provided from the apparatus for driving a piezoelectric actuator 330 to be vibrated. In some exemplary embodiment, the piezoelectric element 510 may have single-layer or multilayered structure.

FIG. 6 is a flowchart for illustrating a method of driving a piezoelectric actuator according to an exemplary embodiment of the present disclosure.

The method of driving a piezoelectric actuator according to the exemplary embodiment to be described below is performed by the apparatus 300 for driving a piezoelectric actuator described above with reference to FIGS. 3 and 4. Accordingly, descriptions on the same or similar elements will not be repeated.

The apparatus 300 for driving a piezoelectric actuator may receive the digital waveform information and may output an analog signal corresponding thereto (S610).

The apparatus 300 for driving a piezoelectric actuator may generate power corresponding to the amplitude of an analog signal by using the digital waveform information (S620).

The apparatus 300 for driving a piezoelectric actuator may generate an analog voltage by amplifying the analog signal based on the power (S630).

Since the amplitude of the analog signal is proportional to the amplitude of the analog voltage, the apparatus 300 may determine the level of power to be output based on the amplitude of the analog signal.

In an exemplary embodiment, the digital waveform information may contain amplitude information relating to the analog voltage. Alternatively, in some exemplary embodiments, the digital waveform information may contain information relating to the analog signal, such as amplitude information.

In an example of operation S620, the apparatus 300 for driving a piezoelectric actuator may generate power by adjusting a resistance value using the amplitude information and performing boost converting using the adjusted resistance value.

As set forth above, according to exemplary embodiments of the present disclosure, efficiency in boosting can be increased and power can be efficiently managed by way of performing boosting, according to the level of an analog voltage to be supplied to a piezoelectric element.

While exemplary embodiments have been shown and described above, it will be apparent to those skilled in the art that modifications and variations could be made without departing from the spirit and scope of the present disclosure as defined by the appended claims.

What is claimed is:

1. An apparatus for driving a piezoelectric actuator, comprising:
a digital-to-analog conversion unit receiving digital waveform information and outputting an analog signal corresponding thereto;
an amplification unit amplifying the analog signal to generate an analog voltage; and
a power supply unit supplying power for the amplification unit, the power supply unit adjusting a level of the power using the digital waveform information.

2. The apparatus of claim 1, wherein the digital waveform information includes amplitude information relating to the analog voltage.

3. The apparatus of claim 2, wherein the digital waveform information further includes at least one of frequency information and period information relating to the analog voltage to be converted.

4. The apparatus of claim 2, wherein the power supply unit includes:
a boost converter generating the power; and
a boost controller determining a boosting ratio for the boost converter using the amplitude information.

5. The apparatus of claim 4, wherein the boost controller includes a plurality of resistance units connected to one another in parallel, and each of the resistance units includes a resistor and a switch connected to each other in series.

6. The apparatus of claim 5, wherein the boost controller performs switching operations on the resistance units using the amplitude information.

7. A system for driving a piezoelectric actuator, comprising:
an apparatus for driving a piezoelectric actuator, the apparatus generating an analog signal corresponding to digital waveform information and amplifying the analog signal to provide an analog voltage; and
a piezoelectric element receiving the analog voltage to vibrate,
wherein the apparatus utilizes power corresponding to an amplitude of the analog signal.

8. The system of claim 7, wherein the apparatus includes:
a digital-to-analog conversion unit receiving digital waveform information and outputting an analog signal corresponding thereto;
an amplification unit amplifying the analog signal to generate an analog voltage; and
a power supply unit supplying power for the amplification, the power supply unit adjusting a level of the power using the digital waveform information.

9. The system of claim 8, wherein the digital waveform information includes amplitude information relating to the analog voltage.

10. The system of claim 9, wherein the power supply unit includes:
a boost converter generating the power; and
a boost controller determining a boosting ratio for the boost converter using the amplitude information.

11. The system of claim 10, wherein the boost controller includes a plurality of resistance units connected to one another in parallel, and each of the resistance units includes a resistor and a switch connected to each other in series.

12. The system of claim 11, wherein the boost controller performs switching operations on the resistance units using the amplitude information.

13. A method of driving a piezoelectric actuator, comprising:
receiving digital waveform information and outputting an analog signal corresponding thereto;
generating power proportional to amplitude of the analog signal using the digital waveform information; and
generating an analog voltage by amplifying the analog signal based on the power.

14. The method of claim 13, wherein the digital waveform information includes amplitude information relating to the analog voltage.

15. The method of claim 14, wherein the generating of the power includes:
adjusting a resistance value using the amplitude information; and
generating the power by performing boost converting using the adjusted resistance value.
